(19) United States
(12) Patent Application Publication
(10) Pub. No.: US 2003/0222339 A1
(43) Pub. Date: Dec. 4, 2003

(54) Wiring substrate and semiconductor device

(75) Inventor: Tatsuya Hirai, Tokyo (JP)

Correspondence Address: McDermott, Will & Emery, 600 13th Street, N.W., Washington, DC, 20005-3096, US

(73) Assignee: MITSUBISHI DENKI KABUSHIKI KAISHA

(21) Appl. No.: 10/299,841

(22) Filed: Nov. 20, 2002

(30) Foreign Application Priority Data
May 30, 2002 (JP) 2002-157696

(51) Int. Cl. H01L 23/48

(52) U.S. Cl. 257/692

(57) ABSTRACT

A wiring substrate comprises a mount portion for mounting a semiconductor chip thereon, a plurality of external terminals to be connected to external electrodes, and a plurality of substrate wires each connected to a respective one of the plurality of external terminals. Each of the plurality of substrate wires includes a plurality of electrode connection portions to be connected to electrodes formed on the surface of the semiconductor chip.

### BACKGROUND OF THE INVENTION

1. Field of the Invention

The present invention relates to a wiring substrate and a semiconductor device. More particularly, the present invention relates to a wiring substrate for mounting a semiconductor chip thereon so as to form a semiconductor device, and a semiconductor device employing the wiring substrate.

2. Background Art

FIG. 13 is a perspective view of a semiconductor device 600 formed using a conventional wiring substrate 610. It should be noted that in the figure, a portion of the device (a portion of a sealing resin 6) has been cut away to reveal the internal structure for explanation.

As shown in FIG. 13, the semiconductor device 600 is manufactured by mounting a semiconductor chip 4 on the wiring substrate 610 and sealing them by use of a sealing resin 6.

The wiring substrate 610 includes a substrate 2, which has metal balls 8 on its rear. The metal balls 8 are connected through throughholes 10 to substrate wires 42 formed on the surface of the substrate 2. Electrodes 14 are provided on the surface of the semiconductor chip 4 and connected to the substrate wires 42 by way of wires 16.

FIG. 14 is a plan view of the semiconductor device 600 with the sealing resin 6 cut away.

As shown in FIG. 14, a center portion of the wiring substrate 610 is covered with a resist 18, and the semiconductor chip 4 is mounted on the resist 18 through die attach components.

The substrate wires 42 each include a wire connection portion (position) 44 and a connection wire 46. The wire connection portions 44 are disposed such that they run along the edges of the substrate 2 in a rectangular shape. One end of each connection wire 46 is connected to a respective wire connection portion 44, while the other end is connected to a connection portion 10 connected to a metal ball.

With the above arrangement, however, even when a semiconductor chip of different size is mounted on the wiring substrate 610, it is also necessary to connect the electrodes 14 of the semiconductor chip 4 to the wire connection portions 44 by way of the wires 16. However, a number of the wire connection portions 44 equal to the number of external electrodes 8 are disposed on the wiring substrate 610 in a single row along the edges of the substrate 2, forming a rectangular, as described above.

Therefore, for example, if the semiconductor chip to be mounted is small, the lengths of the wires 16 must be set to be long. In such a case, the wires 16 easily come into contact with one another when applying the sealing resin 6. If the semiconductor chip to be mounted is large, on the other hand, the electrodes 14 are too close to the wire connection portions 44. As a result, the wires 16 easily come into contact with the edges of the semiconductor chip 4.

If the wires 16 come into contact with one another, as described above, it has a serious impact on the reliability of the semiconductor device itself. Conventionally, to avoid this, when a semiconductor chip of different size is mounted on a wiring substrate, the wiring substrate is newly produced in which the positions of the wire connection portions have been shifted to meet the size of the semiconductor chip.

However, the types and the kinds of semiconductor chips developed have increased in recent years, making it difficult to produce a wiring substrate dedicated for each one of many chip types. Doing so would increase the production time and cost.

### SUMMARY OF THE INVENTION

The present invention has been devised to solve the above problems. It is, therefore, an object of the present invention to provide a semiconductor package substrate capable of accommodating semiconductor chips of different sizes using wires having a length within a predetermined range.

According to one aspect of the present invention, a wiring substrate comprises a mount portion for mounting a semiconductor chip thereon, a plurality of external terminals to be connected to external electrodes, and a plurality of substrate wires each connected to a respective one of the plurality of external terminals. Each of the plurality of substrate wires includes a plurality of electrode connection portions to be connected to electrodes formed on a surface of the semiconductor chip.

In another aspect of the present invention, the plurality of substrate wires may be arranged such that they run along radial lines drawn from a center portion of the wiring substrate.

In another aspect of the present invention, the plurality of electrode connection portions may be disposed such that they form a plurality of rows in circles each running along edges of the mount portion. Each of the plurality of substrate wire includes the electrode connection portions included in two or more different rows selected from among the plurality of rows.

In another aspect of the present invention, a semiconductor device comprises a wiring substrate in the present invention, a semiconductor chip mounted on the wiring substrate and including a plurality of electrodes. Each of the plurality of electrodes on the semiconductor chip is connected to a respective one of the plurality of electrode connection portions included in one of the plurality of substrate wires.

Accordingly, the electrode connection portions at appropriate positions can be used for connection to the electrodes according to the size of a semiconductor chip to be mounted.

In another aspect of the present invention, in the semiconductor device, unnecessary electrode connection portions selected from among the plurality of electrode connection portions included in each of the plurality of substrate wires are covered with a resist.

Accordingly, a highly reliable semiconductor device can be obtained.

Other and further objects, features and advantages of the invention will appear more fully from the following description.

### BRIEF DESCRIPTION OF THE DRAWINGS

FIG. 1 is a perspective view of a semiconductor device according to a first embodiment of the present invention;

FIG. 2 is a plan view of the wiring substrate in the first embodiment of the present invention, illustrating its configuration;

FIG. 3 is a plan view of the semiconductor device in the first embodiment of the present invention with the sealing resin cut away;

FIG. 4 is a perspective view of a semiconductor device according to a second embodiment of the present invention;

FIG. 5 is a plan view of the wiring substrate of the semiconductor device in the second embodiment of the present invention, illustrating its configuration;

FIG. 6 is a plan view of the semiconductor device in the second embodiment of the present invention with the sealing resin cut away;

FIG. 7 is a plan view of a wiring substrate according to a third embodiment of the present invention;

FIG. 8 is a plan view of a semiconductor device in the third embodiment of the present invention with the sealing resin cut away;

FIG. 9 is a plan view of a wiring substrate according to a fourth embodiment of the present invention, illustrating its configuration;

FIG. 10 is a plan view of a semiconductor device in the fourth embodiment of the present invention with the sealing resin cut away;

FIG. 11 is a plan view of a wiring substrate according to a fifth embodiment of the present invention, illustrating its configuration;

FIG. 12 is a plan view of a semiconductor device in the fifth embodiment of the present invention with the sealing resin cut away;

FIG. 13 is a perspective view of a semiconductor device formed using a conventional wiring substrate;

FIG. 14 is a plan view of the semiconductor device with the sealing resin cut away.

### DETAILED DESCRIPTION OF THE PREFERRED EMBODIMENTS

Preferred embodiments of the present invention will be described below with reference to the accompanying drawings. It should be noted that the same or corresponding components in the figures are denoted by like numerals to simplify or omit their explanation.

First Embodiment

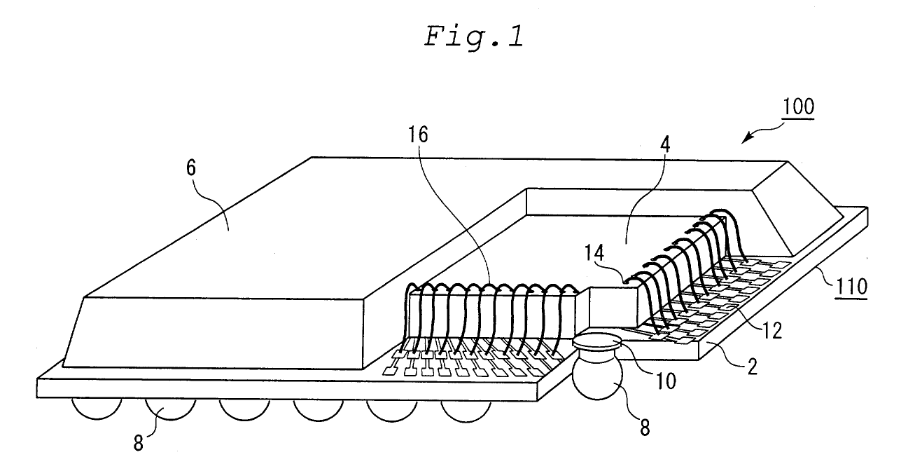

FIG. 1 is a perspective view of a semiconductor device 100 according to a first embodiment of the present invention. It should be noted that in the figure, a portion of the device (a portion of a sealing resin 6) has been cut away to reveal the internal structure for explanation.

As shown in FIG. 1, the semiconductor device 100 includes a wiring substrate 110, a semiconductor chip 4 mounted on the wiring substrate 110, and a sealing resin 6.

The wiring substrate 110 includes a substrate 2, which has metal balls 8 formed on its rear. The metal balls 8 are connected to connection portions 10 formed on the surface of the substrate 2, and the connection portions 10, in turn, are connected to substrate wires 12 formed on the surface of the substrate 2. That is, the metal balls 8 are connected to the substrate wires 12 through the connection portions 10.

A plurality of electrodes 14 are formed on the surface of the semiconductor chip 4. Specifically, the semiconductor chip 4 is mounted on the surface of the wiring substrate 110, and the electrodes 14 are connected to the substrate wires 12 by way of wires 16. In this state, the semiconductor chip 4 is sealed onto the wiring substrate 110 by use of the sealing resin 6, forming the semiconductor device 100.

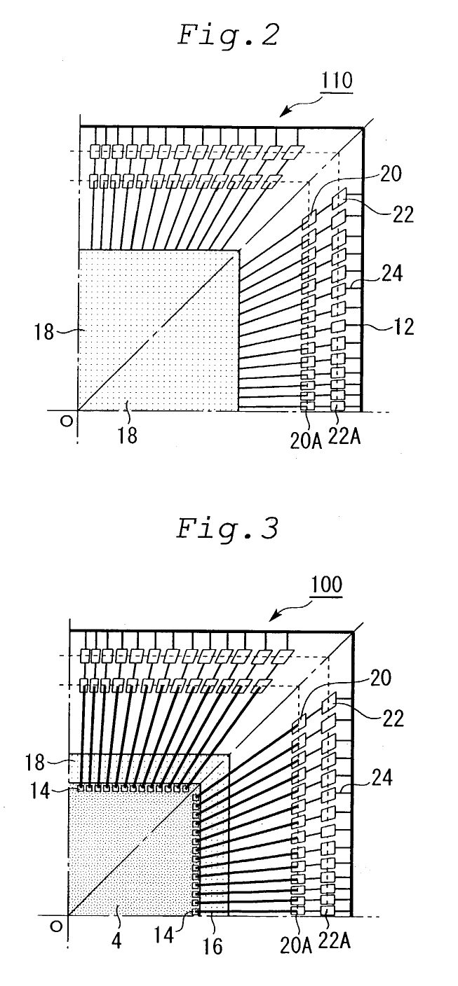

FIG. 2 is a plan view of the wiring substrate 110, illustrating its configuration. It should be noted that the figure shows only the first one (the upper-right portion) of the four quadrants obtained as a result of dividing the wiring substrate 110 by the orthogonal coordinate axes intersecting at the center O. Even though the figure does not show the remaining lower-right, lower-left, and upper-left portions (that is, the second to fourth quadrants), they each have a similar component arrangement, and are symmetrical to one another about the center point O.

As shown in FIG. 2, a center portion of the wiring substrate 110 is covered with a resist 18. Furthermore, the substrate wires 12 are provided on the wiring substrate 110 such that they are disposed in radial fashion around the resist 18 with the center point O at the center. The number of the substrate wires 12 is equal to the number of the electrodes 14 of the semiconductor chip.

Each substrate wire 12 includes two wire connection portions (positions) 20 and 22 and a connection wire 24. One end of each connection wire 24 is connected to respective wire connection portions 22 and 20, while the other end is connected to a connection portion 10.

The wire connection portions 20 and 22 are disposed such that they encircle around the portion covered with the resist 18. The wire connection portions 20 and the wire connection portions 22 are alongside of each other, forming the inner and outer rectangles (or two rows denoted by 20A and 22A), respectively (that is, the wire connection portions 20 are disposed inside). The numbers of the wire connection portions 20 and 22 in the rows 20A and 22A disposed on the entire surface of the wiring substrate 110 are each equal to the number of the electrodes 14 provided on the entire surface of the semiconductor chip 4. It should be noted that the wire connection portions 20 and 22 are formed by applying plating onto a metal such as copper.

Thus, each substrate wire 12 includes: a connection wire 24; and a wire connection portion 20 in the row 20A and a wire connection portion 22 in the row 22A connected to the connection wire 24. Furthermore, each substrate wire 12 is disposed such that it runs in the radial direction from a respective connection portion 10 to the center O.

FIG. 3 is a plan view of the semiconductor device 100 with the sealing resin 6 cut away. FIG. 3 shows only the first quadrant as does FIG. 2.

As shown in FIG. 3, the semiconductor chip 4 is mounted on the portion covered with the resist 18. Each electrode 14 formed on the surface of the semiconductor chip 4 is connected to a respective wire connection portion 20 in the row 20A by way of a wire 16. That is, since the semiconductor chip 4 in the example shown in FIG. 3 is small, the wires 16 are connected to only the wire connection portions 20 in the inner row 20A and not connected to the wire connection portions 22.

In the semiconductor device 100 configured as described above, the wire connection portions 20 are connected through the connection wires 24 to the connection portions 10 connected to the metal balls 8, which are used as terminals to be connected to external electrodes. Furthermore, the electrodes 14 of the semiconductor chip 4 are connected to the wire connection portions 20 by way of the wires 16. With this arrangement, an electric signal can be supplied from the external electrodes to active elements connected to the electrodes 14 in the semiconductor chip 4.

Thus, the wire connection portions 20, disposed inside, may be connected to the electrodes 14 depending the size of the semiconductor chip 4 when the semiconductor chip 4 has a small size. Accordingly, the lengths of the wires 16, which connect between the electrodes 14 and the wire connection portions 20, can be set to be shorter than a predetermined length even when the semiconductor chip 4 is small. Therefore, the wires 16 can be prevented from coming into contact with one another. With this arrangement, a highly reliable semiconductor device can be obtained.

It should be noted that the above description of the first embodiment illustrates an example in which, of the two rows of wire connection portions, only the wire connection portions 20 disposed in the row 20A are used. This selection is effective when the semiconductor chip 4 is small since it is possible to avoid use of the wires 16 having long lengths. However, the present invention is not limited to the case of using such a small semiconductor chip. The present invention can be applied to such a comparatively large semiconductor chip as that of which the connecting the wires 16 to the wire connection portions 20 in the row 20A may bring wires 16 into contact with edges of the semiconductor chip 4. In such a case (where the semiconductor chip 4 is large), the wire connection portions 22 in the row 22A, disposed outside, may be used. Further, either the wire connection portions 20 or 22 may be selectively used for each side of the wiring substrate depending on the size of the semiconductor chip, arranging the wire connection portions in an irregular shape. For example, the wire connection portions 20 in the row 20A may be used along the right and upper edges, and the wire connection portions 22 in the row 22A may be used along the left and bottom edges.

Further, in the first embodiment, 2 rows of wire connection portions are employed, each row forming a rectangle running along the edges of the wiring substrate 110 (the 2 rows are alongside of each other). However, the present invention is not limited to this specific number of rows (2 rows). Any plural number of rows of wire connection portions may be employed as necessary, forming a plurality of rectangles. Also in this case, an appropriate row of wire connection portions may be selected depending on the size of the semiconductor chip 4 to be employed. Furthermore, a different number of rows of wire connection portions may be employed for each side of the wiring substrate. For example, a single row of wire connection portions are disposed along the right and upper edges, and a plurality of rows of wire connection portions are disposed along the left and bottom edges. Also in this case, for the plurality of rows of wire connection portions disposed along the left and bottom edges, the wires 16 may be connected to appropriate wire connection portions. Therefore, a single semiconductor device substrate (a wiring substrate) can be applied to semiconductor chips of different sizes.

Still further, the first embodiment radially arranges the substrate wires 12 so as to provide intervals between the wire connection portions with a safety margin. However, the present invention is not limited to this specific arrangement. Another arrangement, such as arrangement of the substrate wires in the direction parallel or perpendicular to each edge of the wiring substrate 110, may be employed if the arrangement can provide intervals between the wire connection portions with a certain safety margin.

Still further, in the first embodiment, the wire connection portions 20 and 22 are formed by applying plating to a metal such as copper. However, the present invention is not limited to this specific formation method of the wire connection portions.

Still further, in the first embodiment, the unused wire connection portions 22 are sealed with the sealing resin 6 as they are. However, the wire connection portions 22 may be covered with a resist in order to enhance the reliability. Furthermore, even though the first embodiment employs a resist, anything which can protect the wire connection portions may be employed.

Still further, the first embodiment employs a BGA (Ball Grid Array) which has metal balls on its rear side. However, the present invention is not limited to this specific array (BGA). The present invention can be applied to many types of packages such as one using an LGA (Land Grid Array) in which lands are only provided (no metal balls are provided on the rear side). Furthermore, the present invention can be applied to packages in which the electrodes of the semiconductor chip are not connected to the substrate wires by way of wires (using another means instead). Also in this case, each substrate wire may be connected to a plurality of wire connection portions, and one of them may be selected to directly or indirectly connect between an electrode and the substrate wire.

Second Embodiment

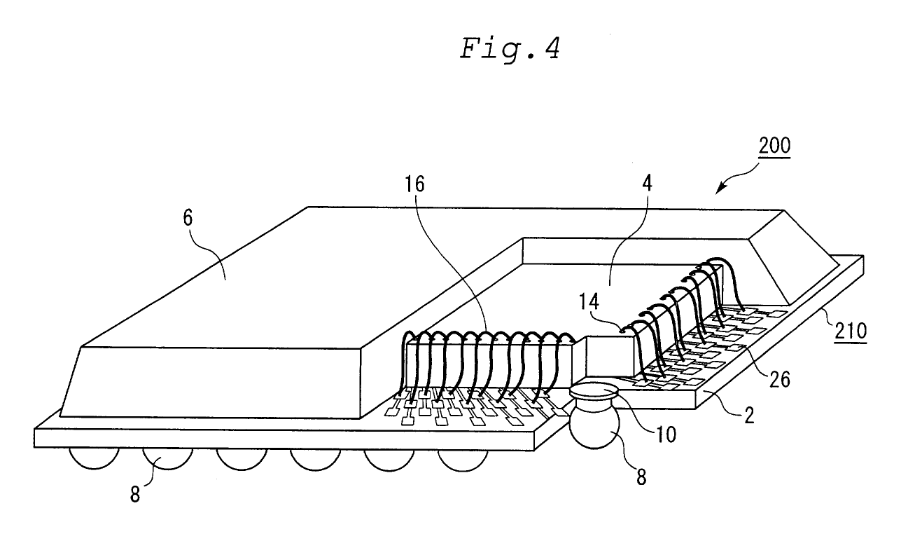

FIG. 4 is a perspective view of a semiconductor device 200 according to a second embodiment of the present invention. It should be noted that in the figure, a portion of the device (a portion of a sealing resin 6) has been cut away to reveal the internal structure for explanation.

As shown in FIG. 4, the semiconductor device 200 includes a wiring substrate 210 and a semiconductor chip 4 mounted on the wiring substrate 210 as in the case of the semiconductor device 100 of the first embodiment. Electrodes 14 on the semiconductor chip 4 are connected to substrate wires 26 formed on the wiring substrate 210 by way of wires 16, and this assembly is sealed with a sealing resin 6 in this state.

Even though the semiconductor device 200 is similar to the semiconductor device 100 as described above, the substrate wires 26 on the wiring substrate 210 are different from the substrate wires 12 on the wiring substrate 110.

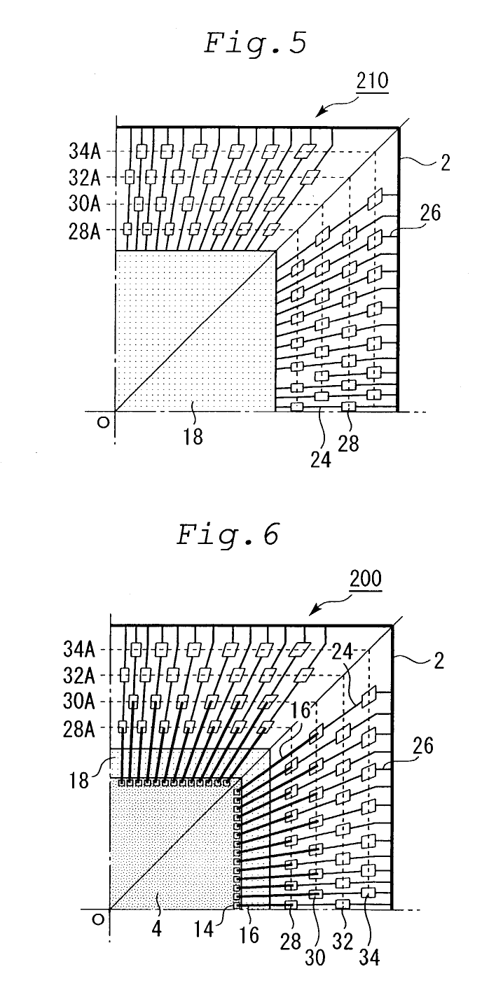

FIG. 5 is a plan view of the wiring substrate 210 of the semiconductor device 200, illustrating its configuration. It should be noted that the figure shows only the first quadrant as does FIG. 2.

As shown in FIG. 5, a center portion of the wiring substrate 210 is covered with a resist 18. Furthermore, the substrate wires 26 are provided on the wiring substrate 210 such that they are disposed in radial fashion around the resist 18 with the center point O at the center. The number of the substrate wires 26 is set to be equal to the number of the electrodes 14 of the semiconductor chip 4.

Each substrate wire 26 includes two wire connection portions 28 and 32, or 30 and 34, and a connection wire 24. One end of each connection wire 24 is connected to respective wire connection portions 28 and 32, or 30 and 34, while the other end is connected to a respective connection portion 10.

The wire connection portions 28, 30, 32, and 34 are disposed such that they encircle around the portion covered with the resist 18 in 4 rows, forming 4 rectangles. Specifically, pluralities of wire connection portions 28, 30, 32, and 34 are disposed around the resist 18 in the four rows 28A, 30A, 32A, and 34A, respectively, arranged alongside of one another in that order in the direction from inside to outside (toward the outer rectangles). The wire connection portions 28 and 32 in the rows 28A and 32A are displaced with respect to the wire connection portions 30 and 34 in the rows 30A and 34A such that radial lines each obtained as a result of connecting a wire connection portion 28 or 32 and the center of the wiring substrate 210 do not intersect with radial lines each obtained as a result of connecting a wire connection portion 30 or 34 and the center. The numbers of the wire connection portions 28, 30, 32, and 34 in the rows 28A, 30A, 32A, and 34A, respectively, disposed on the entire surface of the wiring substrate 21 are each equal to half of the number of the electrodes 14 provided on the entire surface of the semiconductor chip 4.

When one substrate wire 26 includes wire connection portions 28 and 32, another substrate wire 26 adjacent to it includes wire connection portions 30 and 34. That is, a type of substrate wire 26 made up of wire connection portions 28 and 32 and a connection wire 24 connecting the wire connection portions 28 and 32 and another type of substrate wire 26 made up of wire connection portions 30 and 34 and a connection wire 24 connecting the wire connection portions 30 and 34 are disposed alternately on the wiring substrate 210. Furthermore, the substrate wires 26 are each connected to a respective connection portion 10 and disposed radially in the direction from the center O to the connection portion 10.

FIG. 6 is a plan view of the semiconductor device 200 with the sealing resin 6 cut away. FIG. 6 shows only the first quadrant as do FIGS. 2 and 3.

The semiconductor device 200 comprises the wiring substrate 210, configured as described above, and the semiconductor chip 4 mounted on the wiring substrate 210, and is sealed with the sealing resin 6.

As shown in FIG. 6, the semiconductor chip 4 is mounted on the portion covered with the resist 18. Each electrode 14 formed on the surface of the semiconductor chip 4 is connected to either a wire connection portion 28 in the row 28A or a wire connection portion 30 in the 30A on the outer side of the row 28A by way of a wire 16. Specifically, as shown in 6, if one electrode 14 is connected to a wire connection portion 28, another electrode 14 adjacent to it is connected to a wire connection portion 30. Thus, each two neighboring electrodes 14 are connected to different types of wire connection portions (if one is connected to a wire connection portion 28, the other is connected to a wire connection portion 30, and vice versa). That is, a type of substrate wire 26 including wire connection portions 28 and 32 and another type of substrate wire 26 including wire connection portions 30 and 34 are alternately disposed on the wiring substrate 210. Therefore, each wire 16 is connected to an inner wire connection portion 28 or 30 of a substrate wire 26. Since the other components and their arrangements are the same as those of the first embodiment, their explanation will be omitted.

With the above arrangement, either the wire connection portions 28 or 30, disposed on the inner side, may be used depending on the size of the semiconductor device 4. Therefore, the wires 16 can be prevented from setting to be longer than necessary and from coming into contact with one another or coming into contact with the edges of the semiconductor device 4 even when the semiconductor device 4 is small with respect to the wiring substrate 210. Therefore, a highly reliable semiconductor device can be obtained.

Furthermore, according to the second embodiment, which employs 4 rows of wire connection portions, a type of substrate wire 26 made up of wire connection portions 28 and 32 in the rows 28A and 32A and a connection wire 24 connecting the wire connection portions 28 and 32 and another type of substrate wire 26 made up of wire connection portions 30 and 34 in the rows 30A and 34A and a connection wire 24 connecting the wire connection portion 30 and 34 are alternately disposed in radial fashion. With this arrangement, the numbers of wire connection portions 28, 30, 32, and 34 in the rows 28A, 30A, 32A, and 34A, respectively, can be each reduced to half of the number of the electrodes 14 disposed on the semiconductor chip 4, preventing dense arrangement of the wire connection portions.

Further, in the second embodiment, 4 rows of wire connection portions are employed, each row forming a rectangle running along the edges of the wiring substrate 210. However, the present invention is not limited to this specific number of rows (4 rows). Any plural number of rows of wire connection portions (including 4 rows of wire connection portions) may be employed as necessary. Also in this case, when one substrate wire includes (connects) wire connection portions in odd rows (in the example of the second embodiment, the rows 28A and 32A), another substrate wire adjacent to it includes (connects) wire connection portions in even rows (in the example of the second embodiment, the rows 30A and 34A).

Still further, as in the first embodiment, it is not necessary to arrange the substrate wires symmetrically about the center. For example, substrate wires each including only one wire connection portion may be employed on the right and upper sides, while substrate wires of the second embodiment as described above may be employed on the left and bottom sides. This arrangement also makes it possible to mount semiconductor chips 4 of different sizes on a single type of wiring substrate 210.

Still further, even though the second embodiment employs a BGA, the present invention can be applied to many types of packages such as one using an LGA.

Third Embodiment

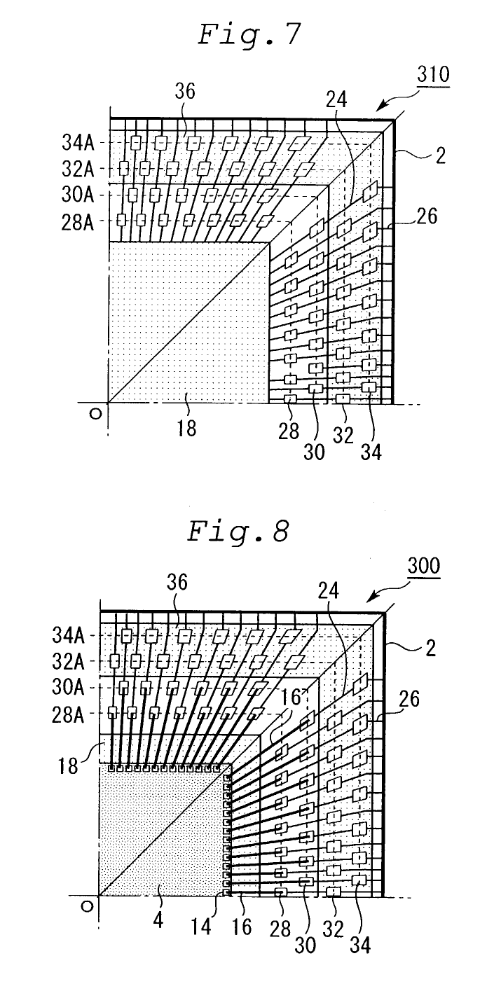

FIG. 7 is a plan view of a wiring substrate 310 according to a third embodiment of the present invention. It should be noted that the figure shows only the first quadrant as does FIG. 2.

The wiring substrate 310 of the third embodiment is similar to the wiring substrate 210 employed in the semiconductor device 200.

However, the wiring substrate 310 of the third embodiment is different from the wiring substrate 210 in that, of the 4 rows of wire connection portions, the wire connection portions 32 and 34 in the rows 32A and 34A disposed on the outer side are covered with a resist 36.

FIG. 8 is a plan view of a semiconductor device 300 with the sealing resin 6 cut away. FIG. 8 shows only the first quadrant as does FIG. 2.

The semiconductor device 300 comprises the wiring substrate 310, configured as described above, and the semiconductor chip 4 mounted on the wiring substrate 310, and is sealed with the sealing resin 6.

As shown in FIG. 8, the semiconductor chip 4 is mounted on the wiring substrate 310 configured as described above, and each two neighboring electrodes 14 on the semiconductor chip 4 are connected to different types of wire connection portions by way of wires 16. That is, if one is connected to a wire connection portion 28, the other is connected to a wire connection portion 30, and vice versa. Furthermore, the wire connection portions 32 and 34 on the outer side, which are not connected to wires 16, are covered with the resist 36 as described above. In this state, the semiconductor chip 4 is sealed onto the wiring substrate 310 with the sealing resin 6.

Since the other components and their arrangements are the same as those of the second embodiment, their explanation will be omitted.

In the semiconductor device 300 described above, the wire connection portions which are not connected to wires 16 are covered with the resist for protection, making it possible to obtain a highly reliable semiconductor device.

It should be noted that in the third embodiment, 4 rows of wire connection portions are employed, forming 4 rectangles which each run along the edges of the wiring substrate 310, each row composed of a respective type of wire connection portions (namely, the wire connection portions 28, 30, 32, or 34), as in the second embodiment. However, the present invention is not limited to this specific number of rows (4 rows). Any plural number of rows may be employed. Furthermore, the substrate wires may be asymmetrically arranged about the center, employing different numbers of rows on the sides. In such a case, the wire connection portions in the unused rows may be covered with a resist.

Further, even though the third embodiment employs a BGA, the present invention can be applied to many types of packages such as one using an LGA.

Fourth Embodiment

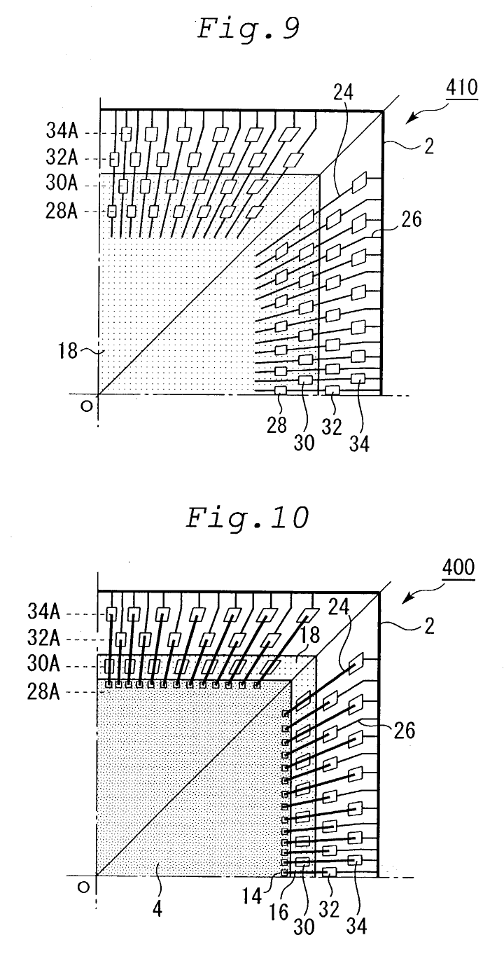

FIG. 9 is a plan view of a wiring substrate 410 according to a fourth embodiment of the present invention, illustrating its configuration. It should be noted that the figure shows only the first quadrant as does FIG. 2.

The wiring substrate 410 of the fourth embodiment is similar to the wiring substrate 210 employed in the semiconductor device 200.

However, the wiring substrate 410 of the fourth embodiment is different from the wiring substrate 210 in that the resist 18 is formed on the substrate 2 such that it reaches the wire connection portions 30 disposed in the row 30A, covering both the wire connection portions 28 and 30.

FIG. 10 is a plan view of a semiconductor device 400 with the sealing resin 6 cut away. FIG. 10 shows only the first quadrant as does FIG. 2.

The semiconductor device 400 comprises the wiring substrate 410, configured as described above, and the semiconductor chip 4 mounted on the wiring substrate 410, and is sealed with the sealing resin 6.

As shown in FIG. 10, the semiconductor chip 4 is mounted on the resist 18. Each two neighboring electrodes 14 on the semiconductor chip 4 are connected to different types of wire connection portions by way of wires 16. That is, if one is connected to a wire connection portion 32, the other is connected to a wire connection portion 34, and vice versa. Specifically, when one electrode 14 is connected to a wire connection portion 32, another electrode 14 adjacent to it is connected to a wire connection portion 34. That is, a wire connection portion 32 and a wire connection portion 34 are alternately used for connection to the electrodes. It should be noted that the fourth embodiment covers the wire connection portions 28 and 30 with the resist 18, and does not use them for connection to the electrodes 14.

Since the other components and their arrangements are the same as those of the first to third embodiments, their explanation will be omitted.

In the fourth embodiment configured as described above, the wire connection portions on the outer side can be used when it is necessary to mount a semiconductor chip 4 of large size. Accordingly, a same wiring substrate 410 can be used for both large and small semiconductor chips.

Further, since the unused wire connection portions are protected by use of the resist 18, a highly reliable semiconductor device can be obtained.

It should be noted that even though the fourth embodiment covers the unused wire connection portions with the resist 18, the present invention is not limited to use of the resist 18.

Still further, in the fourth embodiment, 4 rows of wire connection portions are employed forming 4 rectangles which each run along the edges of the wiring substrate 410, each row composed of a respective type of wire connection portions (namely, the wire connection portions 28, 30, 32, or 34), as in the second embodiment. However, the present invention is not limited to this specific number of rows (4 rows). Any plural number of rows may be employed. Furthermore, the substrate wires may be asymmetrically arranged about the center, employing different numbers of rows on the sides. In such a case, the wire connection portions in the unused rows may be covered with the resist 18.

Still further, even though the fourth embodiment employs a BGA, the present invention can be applied to many types of packages such as one using an LGA.

Fifth Embodiment

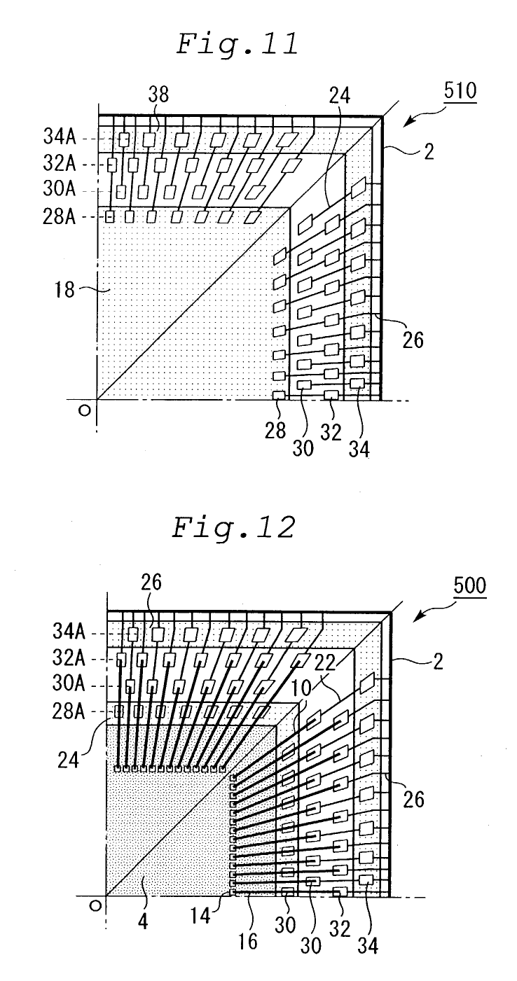

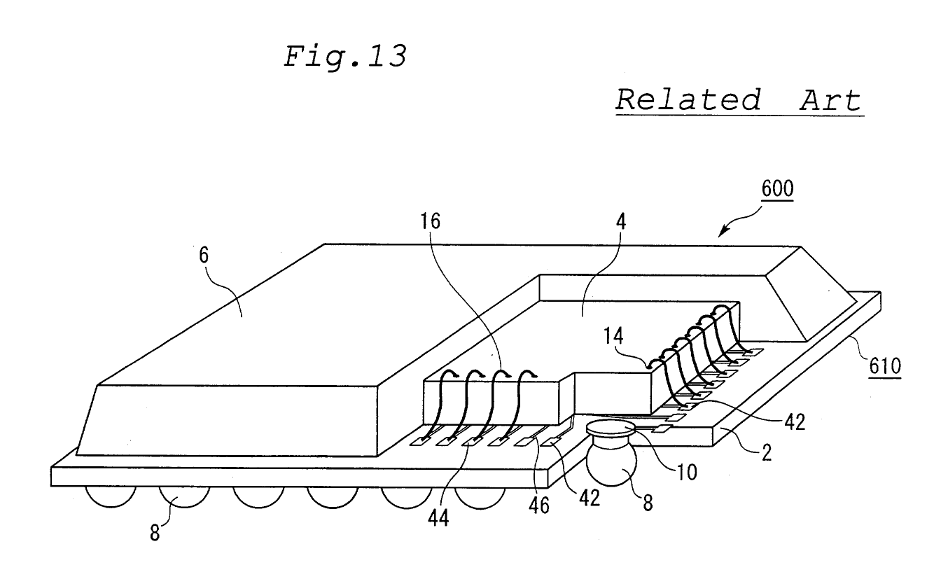

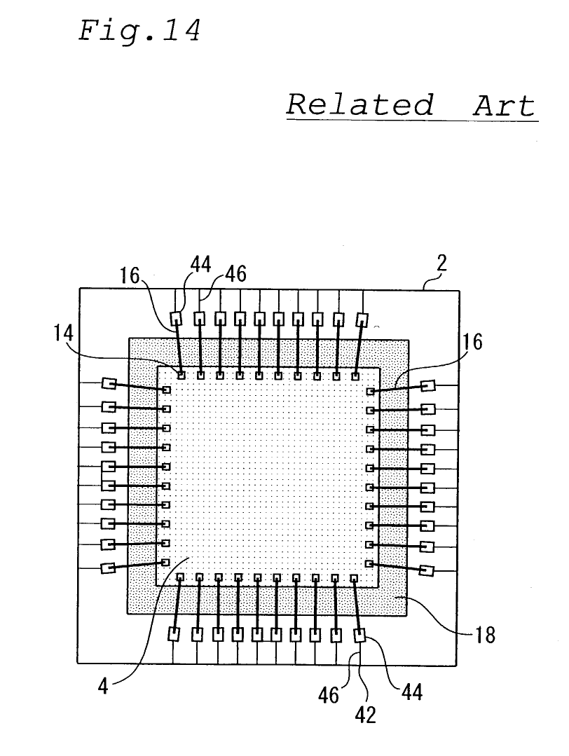

FIG. 11 is a plan view of a wiring substrate 510 according to a fifth embodiment of the present invention, illustrating its configuration. It should be noted that the figure shows only the first quadrant as does FIG. 2.

The wiring substrate 510 of the fifth embodiment is similar to the wiring substrate 210 employed in the semiconductor device 200.

However, as shown in FIG. 11, the wiring substrate 510 of the fifth embodiment is different from the wiring substrate 210 in that the resist 18 reaches and covers the wire connection portions 28 in the row 28A, and the resist 38 covers the wire connection portions 34 in the outermost row 34A.

FIG. 12 is a plan view of a semiconductor device 500 with the sealing resin 6 cut away. FIG. 12 shows only the first quadrant as does FIG. 2.

The semiconductor device 500 comprises the wiring substrate 510 and the semiconductor chip 4 mounted on the wiring substrate 510, and is sealed with the sealing resin 6.

As shown in FIG. 12, the wires 16 are connected to only the wire connection portions 30 and 32 in the rows 30A and 32A and not connected to the wire connection portions 28 and 34 in the rows 28A and 34A. Specifically, when one electrode 14 is connected to a wire connection portion 30 by way of a wire 16, another electrode 14 adjacent to it is connected to a wire connection portion 32 by way of a wire 16. That is, a wire connection portion 30 and a wire connection 32 are alternately used for connection to the electrodes 14.

In the fifth embodiment configured as described above, appropriate wire connection portions can be selected according to the size of the semiconductor chip 4 for connection to the wires 16. Therefore, wiring substrates having a same size can be applied to semiconductor chips of different sizes, making it possible to avoid use of a wire having a length out of a predetermined range. With this arrangement, a highly reliable semiconductor device can be obtained.

It should be noted that even though the fifth embodiment covers the wire connection portions 28 in the innermost row 28A with the resist 18 and the wire connection portions 34 in the outermost row 34A with the resist 38, the present invention is not limited to use of a resist.

Further, in the fifth embodiment, 4 rows of wire connection portions are employed forming 4 rectangles which each run along the edges of the wiring substrate 510, each row composed of a respective type of wire connection portions (namely, the wire connection portions 28, 30, 32, or 34), as in the second embodiment. However, the present invention is not limited to this specific number of rows (4 rows). Any plural number of rows may be employed. Furthermore, the substrate wires may be asymmetrically arranged about the center, employing different number of rows on the sides. In such a case, the unnecessary wire connection portions may be covered with a resist.

Still further, even though the fifth embodiment employs a BGA, the present invention can be applied to many types of packages such as one using an LGA.

It should be noted that the mounting portion of the present invention corresponds to the portion for mounting a semiconductor chip thereon in the wiring substrate, for example, the portion covered with the resist 18 in the first to fifth embodiments. The external terminals of the present invention correspond to the terminals to be connected to external electrodes, for example, the metal balls 8 in the first to fifth embodiments. Furthermore, the electrode connection portions of the present invention correspond to the portions to be directly or indirectly connected to the electrodes formed on the surface of the semiconductor chip, for example, the wire connection portions 20, 22, 28, 30, 32, and 34 in the first to fifth embodiments.

The features and the advantages of the present invention as described above may be summarized as follows.

According to one aspect of the present invention, a plurality of electrode connection portions are included in each substrate wire disposed on the wiring substrate. Accordingly, electrode connection portions at appropriate positions can be used for connection to the electrodes according to the size of a semiconductor chip to be mounted. Therefore, a single type of wiring substrate can be applied to mounting of semiconductor chips of different sizes without the need for employing connection wires having a length out of a predetermined range, making it possible to easily fabricate the semiconductor device. This arrangement eliminates the need for preparing a wiring substrate for each semiconductor chip size, making it possible to obtain a highly reliable semiconductor device and reduce an increase in the production time and cost.

In another aspect, in the present invention, the electrode connection portions which are not connected to the electrodes can be covered with a resist for protection. Accordingly, a highly reliable semiconductor device can be obtained.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2002-157696, filed on May 30, 2002 including specification, claims, drawings and summary, on which the Convention priority of the present application is based, are incorporated herein by reference in its entirety.

What is claimed is:

1. A wiring substrate comprising:
a mount portion for mounting a semiconductor chip thereon;
a plurality of external terminals to be connected to external electrodes; and
a plurality of substrate wires each connected to a respective one of said plurality of external terminals;
wherein each of said plurality of substrate wires includes a plurality of electrode connection portions to be connected to electrodes formed on a surface of said semiconductor chip.

2. The wiring substrate according to claim 1, wherein said plurality of substrate wires are arranged such that they run along radial lines drawn from a center portion of said wiring substrate.

3. The wiring substrate according to claim 1, wherein said plurality of electrode connection portions are disposed such that they form a plurality of rows in circles each running along edges of said mount portion; and
wherein each of said plurality of substrate wires includes said electrode connection portions included in two or more different rows selected from among said plurality of rows.

4. The wiring substrate according to claim 3, wherein said plurality of substrate wires are arranged such that they run along radial lines drawn from a center portion of said wiring substrate.

5. The wiring substrate according to claim 1, wherein said plurality of electrode connection portions are disposed such that they form three or more rows in circles each running along said edges; and
wherein when one of said plurality of substrate wires is connected to an electrode connection portion included in an odd row counting from an innermost row in said wiring substrate, another one of said plurality of substrate wires adjacent to said one of said plurality of substrate wires includes an electrode connection portion included in an even row.

6. The wiring substrate according to claim 5, wherein said plurality of substrate wires are arranged such that they run along radial lines drawn from a center portion of said wiring substrate.

7. A semiconductor device comprising:
the wiring substrate according to claims 1; and
a semiconductor chip mounted on said wiring substrate and including a plurality of electrodes;
wherein each of said plurality of electrodes on said semiconductor chip is connected to a respective one of said plurality of electrode connection portions included in one of said plurality of substrate wires.

8. A semiconductor device comprising:
the wiring substrate according to claim 3; and
a semiconductor chip mounted on said wiring substrate and including a plurality of electrodes;
wherein each of said plurality of electrodes on said semiconductor chip is connected to electrode connection portions which are included in one or more arbitrary rows and selected from among said plurality of electrode connection portions disposed such that they form said plurality of rows in circles each running along said edges.

9. A semiconductor device comprising:
the wiring substrate according to claim 5; and
a semiconductor chip mounted on said wiring substrate and including a plurality of electrodes;
wherein each of said plurality of electrodes on said semiconductor chip is connected to electrode connection portions which are included in one or more arbitrary rows and selected from among said plurality of electrode connection portions disposed such that they form said plurality of rows in circles each running along said edges.

10. The semiconductor device according to claim 7, wherein unnecessary electrode connection portions selected from among said plurality of electrode connection portions included in each of said plurality of substrate wires are covered with a resist.
